(19) United States
(12) Patent Application Publication
(10) Pub. No.: US 2020/0105727 A1
(43) Pub. Date: Apr. 2, 2020

(54) LIGHTING DEVICE

(71) Applicant: SIGNIFY HOLDING B.V., EINDHOVEN (NL)

(72) Inventors: RIFAT ATA MUSTAFA HIKMET, EINDHOVEN (NL); TIES VAN BOMMEL, HORST (NL)

(21) Appl. No.: 16/497,851

(22) PCT Filed: Mar. 26, 2018
(86) PCT No.: PCT/EP2018/057627

§ 371 Date: Sep. 26, 2019

(30) Foreign Application Priority Data
Apr. 6, 2017 (EP) 17165203.5

(51) Int. Cl. H01L 25/075; F21K 9/232

(52) U.S. Cl. CPC H01L 25/0756; F21Y 2107/60; F21K 9/232

(57) ABSTRACT

A lighting device (20) is disclosed, comprising a plurality of light-emitting elements (10a, 10b, 10c, 10d, 10e, 10f, 10g, 10h) arranged in a succession, for example in a stacked arrangement. The lighting device (20) comprises at least one connecting structure (14, 15, 16, 17) arranged to interconnect at least some of the light-emitting elements (10a, 10b, 10c, 10d, 10e, 10f, 10g, 10h), the at least one connecting structure (14, 15, 16, 17) being connected to the at least some of the light-emitting elements (10a, 10b, 10c, 10d, 10e, 10f, 10g, 10h) at respective outer circumferential surfaces (13) thereof. The lighting device (20) may form a linear light source which may be capable of emitting radially along and around the linear light source.

### TECHNICAL FIELD

The present invention relates to a lighting device.

### BACKGROUND

Halogen lamps, filament lamps and discharge lamps are used in various applications such as spot lighting, stage lighting, projection and automotive lighting. Such lamps generally comprise a light-emitting component in the shape of a filament or an arc. The light emitted from the light-emitting component is collected and guided by appropriate optics. For example, in order for the lamp to output collimated light, the light-emitting component, which as indicated in the foregoing may have a filament-shape or an arc-shape, may be positioned in a parabolic reflector. For such halogen lamps, filament lamps and discharge lamps, there is generally desired to decrease the size of the lamps while at the same time increase the brightness of the lamps. Solid state lighting devices, such as light-emitting diode (LED) based lighting devices, may be made relatively small. However, if the size of a solid state lighting device is merely reduced, the light flux that the solid state lighting device is able to generate may decrease.

### SUMMARY

In view of the above discussion, a concern of the present invention is to provide a lighting device which may facilitate or allow for achieving a light-emitting component having a shape similar to a filament or an arc and which may be capable of providing a homogeneous brightness of the light output by the lighting device.

A further concern of the present invention is to provide a lighting device which may facilitate or allow for achieving a light-emitting component having a shape similar to a filament or an arc and which may have a relatively small size, as compared to, for example, halogen lamps, filament lamps or discharge lamps.

To address at least one of these concerns and other concerns, a lighting device in accordance with the independent claim is provided. Preferred embodiments are defined by the dependent claims.

According to a first aspect of the present invention, there is provided a lighting device. The lighting device comprises a plurality of light-emitting elements. Each light-emitting element comprises a first outer end surface at one end of the light-emitting element, a second outer end surface at another end of the light-emitting element, and an outer circumferential (or lateral) surface extending between the first outer end surface and the second outer end surface. Each light-emitting element is configured to emit light at least via at least a portion of the outer circumferential surface of the light-emitting element. The light-emitting elements are arranged in a succession such that at least one of the first outer end surface and the second outer end surface of each light-emitting element is facing in a direction towards a first outer end surface or a second outer end surface of a successive one, or another one, of the light-emitting elements. The lighting device comprises at least one connecting structure arranged to interconnect at least some of the light-emitting elements. The at least one connecting structure is connected to the at least some of the light-emitting elements (which are interconnected by means of the at least one connecting structure) at their respective outer circumferential surfaces.

By means of arranging the light-emitting elements in a succession such that at least one of the first outer end surface and the second outer end surface of each light-emitting element is facing in a direction towards a first outer end surface or a second outer end surface of a successive one of the light-emitting elements, and by means of each light-emitting element being configured to emit light at least via at least a portion of the outer circumferential surface of the light-emitting element, the lighting device may form a linear light source which may be capable of emitting radially along and around the linear light source, which may facilitate or allow for achieving a homogeneous brightness and/or a homogeneous color point of the light output by the lighting device. Also, a relatively high brightness of the light output by the lighting device may be achieved. Also, a light-emitting component may thereby be achieved which for example may have a shape similar to a filament or an arc and which may have a relatively small size, as compared to, for example, halogen lamps, filament lamps or discharge lamps configured so as to have a light-emitting component in the shape of a filament or an arc.

Also, by means of arranging the light-emitting elements in a succession such that at least one of the first outer end surface and the second outer end surface of each light-emitting element is facing in a direction towards a first outer end surface or a second outer end surface of a successive one of the light-emitting elements, thermal management of the lighting device may be facilitated. Heat generated in a light-emitting element when it is operated (e.g., when emitting light) may not be homogeneously distributed over the periphery of the light-emitting element. For example, direct emitting LEDs may generate more heat at one side (e.g., the back) of the LED than at other sides thereof. According to another example, certain phosphor converted LEDs may generate more heat at a location on the LED where the phosphor is arranged on the LED, due to Stokes losses, compared to other locations on the LED. By means of appropriately arranging the light-emitting elements in a succession such that at least one of the first outer end surface and the second outer end surface of each light-emitting element is facing in a direction towards a first outer end surface or a second outer end surface of a successive one of the light-emitting elements, the light-emitting elements may be arranged so that specific sides or surfaces of different light-emitting elements are facing each other, which may facilitate preventing so called hot spots.

Each of the light-emitting elements comprises a substrate and a light-emitting module arranged on a first side of the substrate and a reflector arranged on a second side of the substrate, wherein the substrate, the light-emitting module and the reflector are arranged such that the first outer end surface is located on the reflector and the second outer end surface is located on the light-emitting module. This may further facilitate for achieving a relative high and homogeneous brightness of the light output by the lighting device. The reason is that at least part of the light emitted by the light emitting module is redirected by the reflector towards the outer circumferential surface.

According to one or more embodiments of the present invention, the reflector may have a reflectivity preferably above 80%, more preferably above 85%, and most preferably above 88% such as for example 92 or 95%. The higher the reflectivity of the reflector, the higher the brightness of the light output by the lighting device.

According to one or more embodiments of the present invention, the reflector may provide diffuse reflection. The obtained effect is improved brightness of the light output by the lighting device. The reason is that the light is redirected to other angles.

According to one or more embodiments of the present invention, the light-emitting elements may be arranged in a succession such that the first outer end surfaces of each of the light-emitting elements is facing in a direction towards the second outer end surface of a successive one of the light-emitting elements, except for the first light-emitting element in the succession of light-emitting elements and the last light-emitting element in the succession of light-emitting elements (the first light-emitting element and the last light-emitting element in the succession of light-emitting elements may only facing be another (successive) light-emitting element from one side). This may further facilitate for achieving a homogeneous brightness of the light output by the lighting device, since the intensity of emitted light may be relatively constant along the length of the succession of light-emitting elements. This may also further facilitate preventing so called hot spots if the light-emitting elements are such that heat generated therein when operated (e.g., when emitting light) may not be homogeneously distributed over the periphery of the respective ones of the light-emitting elements, by arranging the light-emitting elements in the succession of light-emitting elements such for two successive light-emitting elements in the succession of light-emitting elements, a side of one light-emitting element which may generate relatively much heat (e.g., the first outer end surface) is directed towards a side of the other light-emitting element which may generate relatively little heat (the second outer end surface). Thus, for two successive light-emitting elements in the succession of light-emitting elements, respective sides of the light-emitting elements which may generate relatively much heat may not be directed towards each other.

The at least some of the light-emitting elements (which are interconnected by means of the at least one connecting structure) may be arranged in a stacked arrangement. The at least some of the light-emitting elements may be arranged in a stacked arrangement such that at least one of the first outer end surface and the second outer end surface of each of the at least some of the light-emitting element is coupled to a first outer end surface or a second outer end surface of a successive one of the at least some of the light-emitting elements. The at least one connecting structure may be arranged to fixate the at least some of the light-emitting elements in the stacked arrangement.

The light-emitting elements may for example comprise or be constituted by LEDs, which may be side-emitting LEDs. Thus, according to one or more embodiments of the present invention, the lighting device may comprise side-emitting LEDs which are arranged in stacked arrangement and which are interconnected at the outer circumferential surfaces of the respective LEDs which are in the stacked arrangement. The (possibly side-emitting) LEDs which are in the stacked arrangement may for example comprise Chip Scale Package (CSP) LEDs. Each of the CSP LEDs may comprise a LED die directly attached to a substrate, and not via a sub-mount. The substrate may for example comprise a sapphire substrate.

All or at least some of the light-emitting elements, e.g., comprising LEDs, may be of the same or similar type. All or at least some of the light-emitting elements may be configured such that the emitted light of the respective ones of the light-emitting elements exhibit the same or similar lighting characteristics.

All or at least some of the light-emitting elements may be configured such that they emit white light having a color temperature in a range from (about) 1000 K to (about) 20000 K, or from (about) 2000 K to (about) 10000 K, or from (about) 2500 K to (about) 6000 K. All or at least some of the light-emitting elements may be configured such that they emit white light that is within 20 Standard Deviations of Color Matching (SDCM) from the Black Body Locus (BBL), or within 10 SDCM from the BBL, or within 5 SDCM from the BBL. All or at least some of the light-emitting elements may be configured such that they emit white light that has a color rendering index (CRI) of at least 60, or a CRI at least 70, or a CRI at least 80.

All or at least some of the light-emitting elements may be shaped such that they have the same or similar geometrical dimensions. Any one or each of the light-emitting elements, e.g., comprising LEDs, may for example be shaped such that it comprises a height H, a first width W1, and a second width (or depth) W2 which may extend in mutually perpendicular directions or substantially mutually perpendicular directions. The first width W1 may for example be in a range between 0.5 mm and 10 mm, such as for example between 1 mm and 2 mm. The second width W2 may for example be in a range between 0.5 mm and 10 mm, such as for example between 1 mm and 2 mm. The first width W1 may be the same or substantially the same as the second width W2. By arranging the light-emitting elements such that the first width W1 thereof is the same or substantially the same as the second width W2 thereof, it may be facilitated to achieve a relatively high brightness of the light output by the lighting device.

For facilitating for achieving a light-emitting component which has a shape similar to a filament or an arc (or so as to mimic a filament or arc), the number of light-emitting elements in the lighting device may be selected so as to exceed a certain number. For example, the number of light-emitting elements in the lighting device may be more than six, or more than eight, or more than ten. Also, by providing a relatively large number of light-emitting elements in the lighting device, a relatively high luminous flux of the light output by the lighting device may be achieved.

The light-emitting component having a shape similar to a filament or an arc achieved by the lighting device may be shaped such that it comprises a length L, a first width W3, and a second width W4 which may extend in mutually perpendicular directions or substantially mutually perpendicular directions. The length L may be at least five times (or at least eight times, or at least ten times) as large as the first width W3 and/or the second width W4. Thereby, a relatively high luminous flux of the light output by the lighting device may be achieved, and it may be facilitated for the light-emitting component to mimic a filament or an arc.

The light-emitting component having a shape similar to a filament or an arc achieved by the lighting device may have an overall light-emitting area A, which may be (about) 40 mm² or more. The luminous flux of the light output by the lighting device may be (about) 2000 lm or more. Thus, the intensity the light output by the lighting device may be (about) 50 lm/mm² or more. The minimum intensity, or brightness, of the light output by the lighting device may be at least 25 lm/mm², or at least 40 lm/mm², or at least 50 lm/mm² or more.

At least one of the first outer end surface and the second outer end surface of each of the at least some of the light-emitting element may be directly coupled to a first outer end surface or a second outer end surface of a successive one of the at least some of the light-emitting elements. However, at least one of the first outer end surface and the second outer end surface of each of the at least some of the light-emitting element may be indirectly coupled to a first outer end surface or a second outer end surface of a successive one of the at least some of the light-emitting elements, for example via one or more intermediate components (e.g., substrate(s)).

The lighting device may comprise a plurality of connecting structures, which may be arranged to interconnect at least some of the light-emitting elements at their respective outer circumferential surfaces. The connecting structures may be connected to each of the at least some of the light-emitting elements at different locations on their respective outer circumferential surfaces. The connecting structures may be connected to each of the at least some of the light-emitting elements while keeping the connecting structures spaced apart from each other. By providing several connecting structures which are arranged to interconnect at least some of the light-emitting elements at their respective outer circumferential surfaces, a relatively high reliability of the interconnection of the succession or stacked arrangement of the light-emitting elements may be achieved.

According to one or more embodiments of the present invention, at least one first connecting structure of the connecting structures may be arranged to interconnect at least a first plurality of the light-emitting elements at their respective outer circumferential surfaces. At least one second connecting structure of the connecting structures may be arranged to interconnect at least a second plurality of the light-emitting elements at their respective outer circumferential surfaces. The first connecting structure and the second connecting structure may for example be configured to provide electrical connection to the first plurality of the light-emitting elements and to the second plurality of the light-emitting elements, respectively. To that end, there may for example be provided at least two first connecting structures, acting as electrode and cathode, respectively, and at least two second connecting structures, acting as electrode and cathode, respectively. The light-emitting elements may for example comprise LEDs, as indicated in the foregoing, or another or other types of solid state light-emitting elements which may be controllable for example with respect to color temperature or intensity of the emitted light. By having the first connecting structure and the second connecting structure providing electrical connection to the first plurality of the light-emitting elements and to the second plurality of the light-emitting elements, respectively, the first plurality of the light-emitting elements and the second plurality of the light-emitting elements, respectively, can for example be separately controlled with respect to, e.g., color temperature or intensity of the emitted light.

Any one or each of the light-emitting elements may comprise a substrate and a light-emitting module arranged on the substrate. The substrate and the light-emitting module may be arranged such that the first outer end surface is located on the substrate and the second outer end surface is located on the light-emitting module. The substrate may for example be made at least in part of sapphire. As indicated in the foregoing, any one or each of the light-emitting elements may for example comprise at least one CSP LED, comprising a light-emitting module in the form of a LED die, which may be directly attached to a substrate (e.g., a sapphire substrate). The light-emitting module may hence for example comprise or be constituted by at least one CSP LED, and/or another type of LED.

As indicated in the foregoing, at least one connecting structure may be configured to provide electrical connection to at least one of the light-emitting elements. To that end, there may for example be provided at least two connecting structures, acting as electrode and cathode, respectively. Thus, at least one connecting structure may in addition to providing for means for interconnecting light-emitting elements also provide means for powering them. The need for any further electrical connections (e.g., wirings or the like), which could possibly block light emitted by the light-emitting elements, may thereby be reduced or even eliminated. At least one connecting structure may be configured to electrically connect at least one of the light-emitting elements to a power supply. At least one connecting structure may be configured to electrically connect at least some of the light-emitting elements in series.

In alternative or in addition, at least one connecting structure may be reflective. By means of arranging the at least one connecting structure so as to be reflective, light loss resulting from any absorption of light emitted by the light-emitting elements by the at least one connecting structure may be reduced or even eliminated.

At least one of the light-emitting elements may comprise a light-emitting module. The lighting device may comprise at least one wavelength-converting element. The at least one wavelength-converting element may be arranged so as to receive at least a portion of the light emitted by the light-emitting module and convert the received light into a selected wavelength range. Possibly, there may be provided at least one wavelength-converting element for each of the light-emitting modules, possibly such that each of the light-emitting elements comprises at least one wavelength-converting element arranged so as to receive at least a portion of the light emitted by the light-emitting module and convert the received light into a selected wavelength range.

The at least one wavelength-converting element may for example comprise a layer or coating of wavelength-converting material (on one or more light-emitting modules), for example including one or more phosphors. In alternative or in addition, the at least one wavelength-converting element may comprise a layer or coating of luminescent material selected from one or more elements in the group of quantum confinement structures, lanthanide complexes, and rare earth metal elements. Some or even all of the light-emitting elements may comprise respective light-emitting modules wherein the light-emitting modules may be provided with a common coating of wavelength-converting material, for example including one or more phosphors. One or more light-emitting modules may be provided with at least one wavelength-converting element, while one or more light-emitting elements (or light-emitting modules) may not comprise at least one wavelength-converting element.

At least some light-emitting elements may comprise respective light-emitting modules wherein the light-emitting modules may be provided with at least one wavelength-converting element. Different light-emitting modules may be provided with different wavelength-converting elements, e.g., different types of wavelength-converting elements. For example, different light-emitting modules may be provided with wavelength-converting elements made of different wavelength-converting material, such that different light-emitting elements may be capable of emitting light of different color.

At least one connecting structure may be arranged so as to exhibit a heat spreading capacity or capability. At least one connecting structure may be arranged so as to transfer any heat generated by the at least some of the light-emitting elements interconnected by the at least one connecting structure away from the respective light-emitting elements. Thus, at least one connecting structure may in addition to providing for means for interconnecting light-emitting elements also provide means for heat management of the lighting device.

The light-emitting elements may be arranged in a succession in a direction along a central axis of the lighting device. For at least one of the light-emitting elements, the circumferential width of the light-emitting element in a direction parallel to the central axis may differ between different portions of the outer circumferential surface of the light-emitting element. That is, the circumferential width of the light-emitting element in a direction parallel to the central axis may be different at different portions of the outer circumferential surface of the light-emitting element.

For example, for at least one of the light-emitting elements, the first outer end surface and the second outer end surface of the light-emitting element may be flat, or substantially flat. For the at least one of the light-emitting elements, the first outer end surface of the light-emitting element and the second outer end surface of the light-emitting element may be arranged at an angle to each other. In other words, at least one of the light-emitting elements may be arranged such that the first outer end surface of the light-emitting element and the second outer end surface of the light-emitting element are not parallel. Such a configuration may facilitate for emission of light from the at least one light-emitting element via at least the outer circumferential surface thereof.

At least a portion of the outer circumferential surface of at least one of the light-emitting elements may be flat.

At least a portion of the outer circumferential surface of at least one of the light-emitting elements may be non-flat. This may facilitate for achieving a homogeneous brightness of the light output by the lighting device. For example, at least a portion of the outer circumferential surface of at least one of the light-emitting elements may be shaped in a manner for obtaining a desired distribution or shape of the light emitted via the at least a portion of the outer circumferential surface.

The light-emitting elements may be arranged in a succession (e.g., stacked) in a direction along a central axis of the lighting device.

At least two light-emitting elements may be arranged so as to be offset, or shifted, from one another in a direction perpendicular to the direction along the central axis of the lighting device in which the light-emitting elements are arranged. This may further facilitate for achieving a homogeneous brightness of the light output by the lighting device.

In alternative or in addition, at least two light-emitting elements may be arranged so as to be rotated with respect to each other about the central axis or about an axis parallel to the central axis. This may further facilitate for achieving a homogeneous brightness of the light output by the lighting device.

Possibly, at least two light-emitting elements may be arranged so as to be offset from one another in a direction perpendicular to the direction along the central axis of the lighting device in which the light-emitting elements are arranged, and so as to be rotated with respect to each other about the central axis or about an axis parallel to the central axis.

Any offset and/or rotation of at least two light-emitting elements relatively to each other may be relatively small while still increasing the homogeneousness of the brightness of the light output by the lighting device.

Each or any one of the light-emitting elements or light-emitting modules may for example include or be constituted by a solid state light emitter. Examples of solid state light emitters include light-emitting diodes (LEDs) and organic LEDs (OLEDs). Solid state light emitters are relatively cost efficient light sources since they in general are relatively inexpensive and have a relatively high optical efficiency and a relatively long lifetime. However, in the context of the present application, the term “light-emitting element” or “light-emitting module” should be understood to mean substantially any device or element that is capable of emitting radiation in any region or combination of regions of the electromagnetic spectrum, for example the visible region, the infrared region, and/or the ultraviolet region, when activated e.g. by applying a potential difference across it or passing a current through it. Therefore, a light-emitting element or light-emitting module can have monochromatic, quasi-monochromatic, polychromatic or broadband spectral emission characteristics. Examples of light-emitting elements or light-emitting modules include semiconductor, organic, or polymer/polymeric LEDs, violet LEDs, blue LEDs, optically pumped phosphor coated LEDs, optically pumped nano-crystal LEDs or any other similar devices as would be readily understood by a person skilled in the art. Furthermore, the term light-emitting element or light-emitting module can, according to one or more embodiments of the present invention, mean a combination of the specific light-emitting element(s) or light-emitting module(s) which emit the radiation in combination with a housing or package within which the specific light-emitting element(s) or light-emitting module(s) are positioned or arranged. For example, the term light-emitting element or light-emitting module can encompass a bare LED die arranged in a housing, which may be referred to as a LED package. According to another example, the light-emitting element or light-emitting module may comprise a CSP LED, which may comprise a LED die directly attached to a substrate such a Printed Circuit board (PCB), and not via a sub-mount.

According to a second aspect of the present invention, there is provided a lamp or a luminaire, which comprises at least one lighting device according to the first aspect. The lamp may for example comprise a filament lamp, such as a halogen, or incandescent replacement lamp, or an arc lamp, such as a high pressure sodium replacement lamp. The luminaire may for example comprise a street luminaire or a street light. The lamp or luminaire may for example be used in one or more of the following applications: digital projection, automotive lighting, stage lighting shop lighting, home lighting, accent lighting, spot lighting, theater lighting, fiber optic lighting, display systems, warning lighting systems, medical lighting applications, decorative lighting applications. Further objects and advantages of the present invention are described in the following by means of exemplifying embodiments. It is noted that the present invention relates to all possible combinations of features recited in the claims. Further features of, and advantages with, the present invention will become apparent when studying the appended claims and the description herein. Those skilled in the art realize that different features of the present invention can be combined to create embodiments other than those described herein.

### BRIEF DESCRIPTION OF THE DRAWINGS

Exemplifying embodiments of the invention will be described below with reference to the accompanying drawings.

FIG. 1 is a very schematic view of a light-emitting element in accordance with an embodiment of the present invention.

FIGS. 2 to 4 are very schematic side views of lighting devices according to embodiments of the present invention.

FIG. 5 is a very schematic view from the above of a lighting device according to an embodiment of the present invention.

FIGS. 6 and 7 are very schematic side views of lighting devices according to embodiments of the present invention.

FIGS. 8 and 9 are very schematic side views of lighting devices according to embodiments of the present invention.

FIGS. 10 and 11 are schematic views of lamps according to embodiments of the present invention.

FIG. 12 is a schematic view of a luminaire according to an embodiment of the present invention.

All the figures are schematic, not necessarily to scale, and generally only show parts which are necessary in order to elucidate embodiments of the present invention, wherein other parts may be omitted or merely suggested.

### DETAILED DESCRIPTION

The present invention will now be described hereinafter with reference to the accompanying drawings, in which exemplifying embodiments of the present invention are shown. The present invention may, however, be embodied in many different forms and should not be construed as limited to the embodiments of the present invention set forth herein; rather, these embodiments of the present invention are provided by way of example so that this disclosure will convey the scope of the invention to those skilled in the art. In the drawings, identical reference numerals denote the same or similar components having a same or similar function, unless specifically stated otherwise.

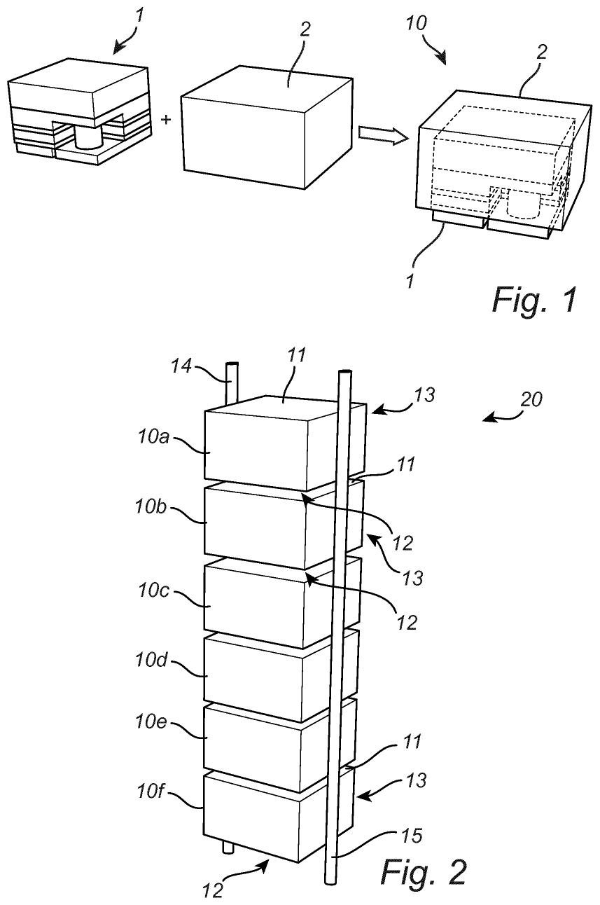

FIG. 1 is a very schematic view of a light-emitting element 10 in accordance with an embodiment of the present invention. In accordance with the illustrated embodiment of the present invention, the light-emitting element 10 comprises a light-emitting module 1 comprising a side-emitting light-emitting diode (LED) in the form of a Chip Scale Package (CSP) LED 1. As illustrated in FIG. 1, the LED 1 may be provided with a wavelength-converting element 2 in the form of a coating of wavelength-converting material on the LED 1. The coating of wavelength-converting material may for example include one or more phosphors. The wavelength-converting element 2 is arranged so as to receive at least a portion of the light emitted by the LED 1 and convert the received light into a selected wavelength range, which may be output by the light-emitting element 10.

FIG. 2 is a very schematic view of a lighting device 20 according to an embodiment of the present invention. The lighting device 20 comprises a plurality of light-emitting elements 10a, 10b, 10c, 10d, 10e, 10f. In accordance with the embodiment of the present invention illustrated in FIG. 2, each of the of light-emitting elements 10a-10f comprises a light-emitting module and a wavelength-converting element in the form of a layer of coating of wavelength-converting material on the light-emitting module. Each of the light-emitting elements 10a, 10b, 10c, 10d, 10e, 10f may for example be configured identical or similar to the light-emitting element 10 illustrated in FIG. 1. It is to be understood that the number of light-emitting elements included in the lighting device 20 is according to an example, and that the number of light-emitting elements included in the lighting device 20 could be less or more than illustrated in FIG. 2. It is further to be understood that the shape of the light-emitting elements 10a-10f illustrated in FIG. 2 is according to an example, and that the shapes of each or any one of the light-emitting elements 10a-10f illustrated in FIG. 2 could be different from what is illustrated in FIG. 2.

Each light-emitting element 10a-10f comprises a first outer end surface 11 at one end of the light-emitting element 10a-10f, a second outer end surface 12 at another end of the light-emitting element, and an outer circumferential surface 13 extending between the first outer end surface and the second outer end surface. In FIG. 2, the first outer end surface 11, the second outer end surface 12 and the outer circumferential surface 13 are indicated by reference numerals for the light-emitting elements 10a, 10b and 10f only.

Each of the light-emitting elements 10a-10f is configured to emit light at least via at least a portion of the outer circumferential surface 13 of the light-emitting element 10a-10f.

The light-emitting elements 10a-10f are arranged in a succession such that at least one of the first outer end surface 11 and the second outer end surface 12 of each light-emitting element 10a-10f is facing in a direction towards a first outer end surface 11 or a second outer end surface 12 of a successive one of the light-emitting elements 10a-10f. Possibly, there may be a (relatively small) distance between adjacent light-emitting elements 10a-10f, as indicated in FIG. 2. The distance between adjacent light-emitting elements, as indicated in FIG. 2, may be effected by means of spacers (not shown in FIG. 2), which may be positioned intermediate one or more pairs of adjacent light-emitting elements. Relatively thin, reflective spacers may be used to reflect light. By means of such spacers, light losses from the light-emitting elements of the lighting device 20 may be kept relatively low, whereby the brightness of the light emitted by the lighting device 20 may become relatively high. The spacer(s) may form layers which are electrically non-conductive, or electrically isolating, whereby adjacent light-emitting elements may be electrically isolated from each other. The spacer(s) may in alternative or in addition be configured so as to guide light. For example, the spacer(s) may comprise relatively thin ceramic or glass plates, Light emitted by the light-emitting elements may be coupled into spacer(s) with light-guiding capability, thereby facilitating for light to be output from the lighting device 20.

The spacer(s) may be made of electrically isolating material.

The spacer(s) may be made of thermally conductive material. This may help to improve thermal management of the lighting device 20 and to remove the heat generated by the one or more of the light emitting elements 10a-10f. The thermal conductivity of the spacer(s) may be at least 400 W m⁻¹ K⁻¹. According to some examples, the thermal conductivity of the spacer(s) may be at least 150 W m⁻¹ K⁻¹, or at least 180 W m⁻¹ K⁻¹. For example, the spacer(s) may be made of one or more metals or metallic materials, such as aluminum, iron, steel and/or copper. For example, the thermal conductivity of any spacer(s) made of aluminum may be about 200 W m⁻¹ K⁻¹, the thermal conductivity of any spacer(s) made of copper may be about 400 W m⁻¹ K⁻¹, and the thermal conductivity of any spacer(s) made of sapphire may be about 100 W m⁻¹ K⁻¹. The light-emitting elements 10a-10f could be arranged in a stacked arrangement such that at least one of the first outer end surface 11 and the second outer end surface 12 of each of the light-emitting element 10a-10f is coupled—possibly directly coupled—to a first outer end surface 11 or a second outer end surface 12 of a successive one of the light-emitting elements 10a-10f. At least one of the first outer end surface 11 and the second outer end surface 12 of each of the light-emitting elements 10a-10f may possibly be indirectly coupled to a first outer end surface 11 or a second outer end surface 12 of a successive one of the light-emitting elements 10a-10f, for example via one or more intermediate components (e.g., substrate(s)).

Each the light-emitting elements 10a-10f may comprise a substrate and a light-emitting module arranged on the substrate. For each the light-emitting elements 10a-10f, the substrate and the light-emitting module may be arranged such that the first outer end surface 11 is located on the substrate and the second outer end surface 12 is located on the light-emitting module. As described in the foregoing, each the light-emitting elements 10a-10f may for example comprise or be constituted by a CSP LED, wherein the CSP LED may comprise a LED die directly attached to a substrate, and not via a sub-mount. The substrate may for example comprise a sapphire substrate. In the light of the foregoing description, the light-emitting elements 10a-10f could hence be arranged so as to be stacked on the (sapphire) substrates thereof.

The lighting device 20 comprises two connecting structures 14, 15 arranged to interconnect the light-emitting elements 10a-10f. As illustrated schematically in FIG. 2, the connecting structures 14, 15 are connected to the respective ones of the light-emitting elements 10a-10f at their respective outer circumferential surfaces 13. According to the embodiment of the present invention illustrated in FIG. 2, the connecting structures 14, 15 are arranged to fixate the light-emitting elements 10a-10f in the succession or stacked arrangement. It is to be understood that the number of connecting structures included in the lighting device 20 is according to an example, and that the number of connecting structures included in the lighting device 20 could be less or more than illustrated in FIG. 2. It is further to be understood that the shape or form of the connecting structures 14, 15 illustrated in FIG. 2 is according to an example, and that the shape or form of each or any one of the connecting structures 14, 15 illustrated in FIG. 2 could be different from what is illustrated in FIG. 2. Thus, although FIG. 2 (and the other figures) illustrates the connecting structures 14, 15 as being straight, or substantially straight, elongated members, this is not required. For example, one or more of the connecting structures 14, 15 illustrated in FIG. 2 (or in any other embodiment of the present invention described herein) could in alternative be configured so as to exhibit a helical shape, surrounding at least some of the light-emitting elements 10a-10f in the succession of light-emitting elements 10a-10f.

Although FIG. 2 illustrates that each of the connecting structures 14, 15 is arranged to interconnect all of the light-emitting elements 10a-10f, this is not required. For example, the connecting structure 14 could be arranged to interconnect some of the light-emitting elements 10a-10f, and the connecting structure 15 could be arranged to interconnect some of the light-emitting elements 10a-10f. Possibly, the connecting structure 14 could be arranged to interconnect a first set of the light-emitting elements 10a-10f, and the connecting structure 15 could be arranged to interconnect a second set of the light-emitting elements 10a-10f. Thereby, the connecting structure 14 could be arranged to provide electrical connection to the first set of the light-emitting elements 10a-10f, and the connecting structure 15 could be arranged provide electrical connection to the second set of the light-emitting elements 10a-10f, facilitating or allowing for example for separately controlling the first set of the light-emitting elements 10a-10f and the second set of the light-emitting elements 10a-10f, respectively, with respect to, e.g., color temperature or intensity of the emitted light.

By arranging the light-emitting elements 10a-10f in a succession such that at least one of the first outer end surface 11 and the second outer end surface 12 of each light-emitting element 10a-10f is facing in a direction towards a first outer end surface 11 or a second outer end surface 12 of a successive one of the light-emitting elements 10a-10f, and by each light-emitting element 10a-10f being configured to emit light at least via at least a portion of the outer circumferential surface 13 of the respective light-emitting element 10a-10f, the lighting device 20 may form a linear light source which may be capable of emitting radially along and around the linear light source, which may facilitate or allow for achieving a homogeneous brightness of the light output by the lighting device 20. Also, the lighting device 20 may thereby provide for a light-emitting component which for example may have a shape similar to a filament or an arc and which may have a relatively small size, as compared to, for example, halogen lamps, filament lamps or discharge lamps configured so as to have a light-emitting component in the shape of a filament or an arc.

It is to be understood that although FIG. 2 and the other figures illustrates the light-emitting elements 10a-10f being arranged in a succession in a straight, or substantially straight, direction, this is not required. For example, the light-emitting elements 10a-10f could be arranged in a succession so as to exhibit a helical shape. This may further facilitate for achieving a homogeneous brightness the light output by the lighting device 20.

The connecting structure 14 and/or the connecting structure 15 may be arranged so as to exhibit a heat spreading capacity or capability. In alternative or in addition, the connecting structure 14 and/or the connecting structure 15 may be configured to provide electrical connection to the light-emitting elements 10a-10f, for example so as to electrically connect the light-emitting elements 10a-10f to a power supply (not shown in FIG. 2) for powering the light-emitting elements 10a-10f As indicated in FIG. 2, the connecting structure 14 and/or the connecting structure 15 may be configured to electrically connect the light-emitting elements 10a-10f in series.

In accordance with the embodiment of the present invention illustrated in FIG. 2, each of the light-emitting elements 10a-10f comprises a wavelength-converting element in the form of a coating or layer of wavelength-converting material, for example including one or more phosphors, at least on the light-emitting module of the light-emitting element 10a-10f The wavelength-converting elements, e.g., wavelength-converting material, may be arranged to receive at least a portion of the light emitted by the respective ones of the light-emitting modules of the light-emitting elements 10a-10f and convert the received light into a selected wavelength range.

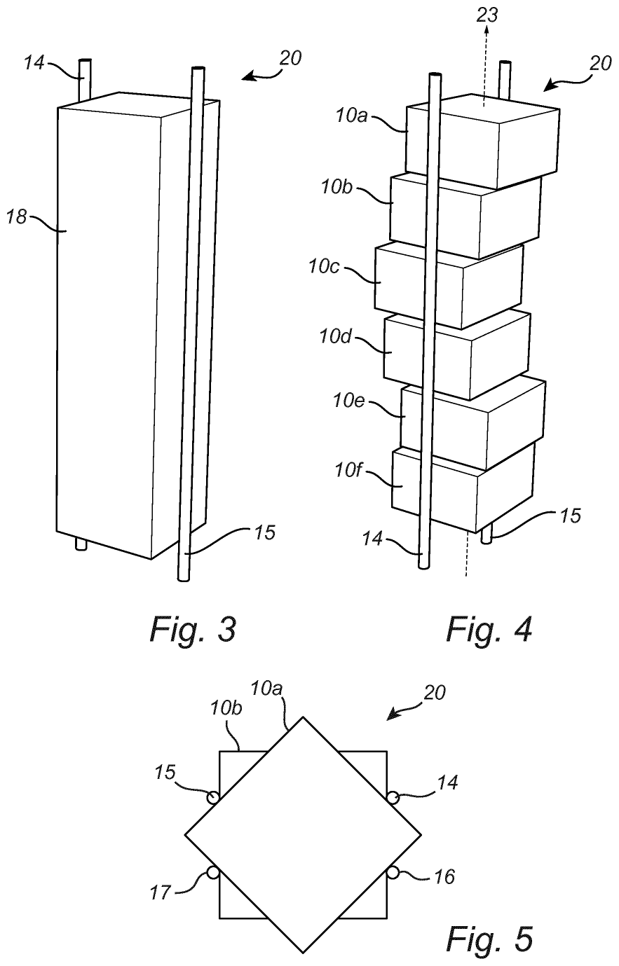

In alternative, all of the light-emitting elements 10a-10f may ‘share’ a common wavelength-converting element 18 for example in the form of a common coating or layer of wavelength-converting material 18, which is schematically illustrated in FIG. 3. The same reference numerals in FIGS. 2 and 3 indicate the same or similar components, having the same or similar function. The coating or layer of wavelength-converting material 18 may for example including one or more phosphors. The wavelength-converting material is not limited to one or more phosphors, but could in alternative or in addition comprise luminescent material selected from one or more elements in the group of quantum confinement structures, lanthanide complexes, and rare earth metal elements.

FIG. 4 is a very schematic view of a lighting device 20 according to an embodiment of the present invention. The lighting device 20 illustrated in FIG. 4 is similar to the lighting device 20 illustrated in FIG. 2, and the same reference numerals in FIGS. 2 and 4 indicate the same or similar components, having the same or similar function.

The lighting device 20 illustrated in FIG. 4 differs from the lighting device 20 illustrated in FIG. 2 in that the light-emitting elements 10a-10f of the lighting device 20 illustrated in FIG. 4 are arranged in a succession in a direction along a central axis of the lighting device 20, schematically indicated by reference numeral 23, and that the light-emitting elements 10a-10f are arranged so as to be offset, or shifted, from one another in a direction perpendicular to the direction along the central axis 23 of the lighting device 20 in which the light-emitting elements 10a-10f are arranged. This may further facilitate for achieving a homogeneous brightness of the light output by the lighting device 20. As illustrated in FIG. 4, different light-emitting elements may be offset, or shifted, in different directions perpendicular to the direction along the central axis 23 of the lighting device 20.

FIG. 5 is a very schematic view from the above of a lighting device 20 according to an embodiment of the present invention. The lighting device 20 illustrated in FIG. 5 is similar to the lighting devices 20 illustrated in FIGS. 2 and 4, and the same reference numerals in FIG. 5 and in FIGS. 2 and 4 indicate the same or similar components, having the same or similar function.

The lighting device 20 illustrated in FIG. 5 differs from the lighting devices 20 illustrated in FIGS. 2 and 4 in that the lighting device 20 illustrated in FIG. 5 comprises two additional connecting structures 16, 17. The connecting structures 14, 15, 16, 17 are arranged to interconnect the light-emitting elements 10a-10f (only the light-emitting elements 10a and 10b are shown in FIG. 5). The connecting structures 14, 15, 16, 17 are connected to the respective ones of the light-emitting elements 10a-10f at their respective outer circumferential surfaces. It is however to be understood that the number of connecting structures included in the lighting device 20 illustrated in FIG. 5 is according to an example, and that the number of connecting structures included in the lighting device 20 could be less or more than illustrated in FIG. 5.

The lighting device 20 illustrated in FIG. 5 differs from the lighting devices 20 illustrated in FIGS. 2 and 4 in that in the lighting device 20 illustrated in FIG. 5, the light-emitting elements 10a-10f are arranged in a succession in a direction along a central axis (not shown in FIG. 5) of the lighting device 20, and in that at least two light-emitting elements—e.g., light-emitting elements 10a and 10b, as illustrated in FIG. 5—are arranged so as to be rotated with respect to each other about the central axis of the lighting device 20 or about an axis parallel to the central axis. This may further facilitate for achieving a homogeneous brightness of the light output by the lighting device 20.

The embodiments of the present invention illustrated in FIGS. 4 and 5 could be combined, so that at least two light-emitting elements may be arranged so as to be offset from one another in a direction perpendicular to the direction along the central axis of the lighting device in which the light-emitting elements are arranged, and so as to be rotated with respect to each other about the central axis or about an axis parallel to the central axis.

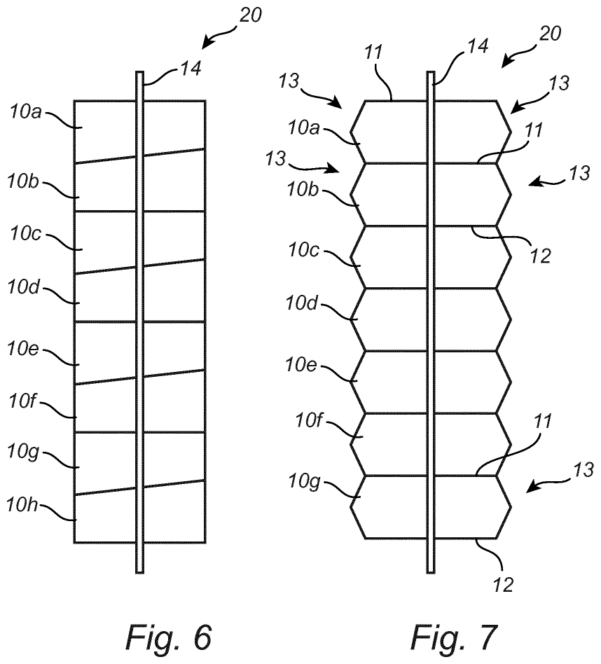

FIG. 6 is a very schematic side view of a lighting device 20 according to an embodiment of the present invention. The lighting device 20 illustrated in FIG. 6 is similar to the lighting device 20 illustrated in FIG. 2, and the same reference numerals in FIGS. 2 and 6 indicate the same or similar components, having the same or similar function.

The lighting device 20 illustrated in FIG. 6 differs from the lighting device 20 illustrated in FIG. 2 in that the lighting device 20 illustrated in FIG. 6 comprises two additional light-emitting elements 10g and 10h. The light-emitting elements 10a-10h are arranged in a stacked arrangement such that at least one of the first outer end surface 11 and the second outer end surface 12 of each of the light-emitting element 10a-10h is coupled—possibly directly coupled—to a first outer end surface 11 or a second outer end surface 12 of a successive one of the light-emitting elements 10a-10h. It is however to be understood that the number of light-emitting elements included in the lighting device 20 illustrated in FIG. 6 is according to an example, and that the number of light-emitting elements included in the lighting device 20 could be less or more than illustrated in FIG. 6. The light-emitting elements 10a-10h are arranged in a stacked arrangement in a direction along a central axis of the lighting device 20.

The lighting device 20 illustrated in FIG. 6 further differs from the lighting device 20 illustrated in FIG. 2 in that in the lighting device 20 illustrated in FIG. 6, for each of the light-emitting elements 10a-10h, the circumferential width of the light-emitting element 10a-10h in a direction parallel to the central axis differs between different (e.g., at least two) portions of the outer circumferential surface 13 of the light-emitting element 10a-10h. For example, according to the embodiment of the present invention illustrated in FIG. 6, for each of the light-emitting elements 10a-10h, the first outer end surface 11 of the light-emitting element 10a-10h and the second outer end surface 12 of the light-emitting element 10a-10h are arranged at an angle to each other. In other words, each of the light-emitting elements 10a-10h is arranged such that the first outer end surface 11 of the light-emitting element 10a-10h and the second outer end surface 12 of the light-emitting element 10a-10h are not parallel. Such a configuration may facilitate for emission of light from the light-emitting elements 10a-10h via the respective outer circumferential surfaces 13 thereof, e.g. for side emission from the light-emitting elements 10a-10h. As illustrated in FIG. 6, the first outer end surface 11 and the second outer end surface 12 of each light-emitting element 10a-10h may be flat, or substantially flat.

FIG. 7 is a very schematic side view of a lighting device 20 according to an embodiment of the present invention. The lighting device 20 illustrated in FIG. 7 is similar to the lighting device 20 illustrated in FIG. 2, and the same reference numerals in FIGS. 2 and 7 indicate the same or similar components, having the same or similar function.

The lighting device 20 illustrated in FIG. 7 differs from the lighting device 20 illustrated in FIG. 2 in that the lighting device 20 illustrated in FIG. 7 comprises an additional light-emitting element 10g. The light-emitting elements 10a-10g are arranged in a stacked arrangement such that at least one of the first outer end surface 11 and the second outer end surface 12 of each of the light-emitting element 10a-10g is coupled—possibly directly coupled—to a first outer end surface 11 or a second outer end surface 12 of a successive one of the light-emitting elements 10a-10g. It is however to be understood that the number of light-emitting elements included in the lighting device 20 illustrated in FIG. 7 is according to an example, and that the number of light-emitting elements included in the lighting device 20 could be less or more than illustrated in FIG. 7.

The lighting device 20 illustrated in FIG. 7 differs from the lighting device 20 illustrated in FIG. 2 in that in the lighting device 20 illustrated in FIG. 7, the outer circumferential surfaces 13 of the light-emitting elements 10a-10g are non-flat and shaped as illustrated in FIG. 7, which may facilitate for achieving a homogeneous brightness of the light output by the lighting device 20. It is to be understood that the outer circumferential surfaces 13 of the light-emitting elements 10a-10g may be shaped in another manner than illustrated in FIG. 7 for obtaining a desired distribution or shape of the light emitted via the outer circumferential surfaces 13 of the light-emitting elements 10a-10g.

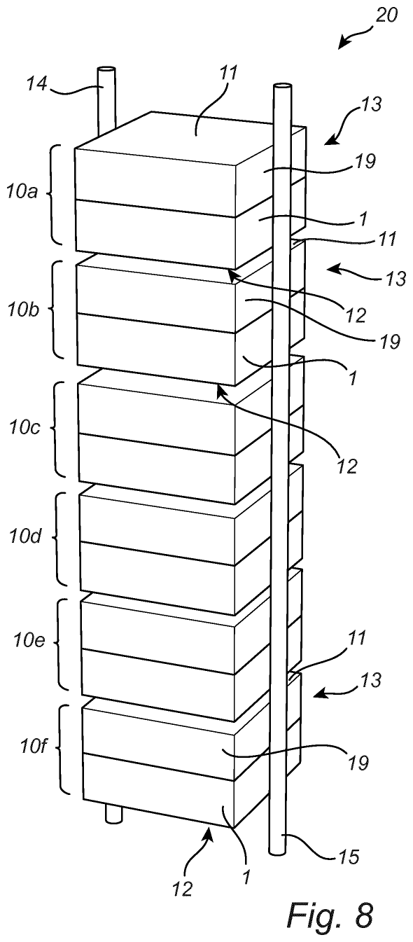

FIG. 8 is a very schematic side view of a lighting device 20 according to an embodiment of the present invention. The lighting device 20 illustrated in FIG. 8 is similar to the lighting device 20 illustrated in FIG. 2, and the same reference numerals in FIGS. 2 and 8 indicate the same or similar components, having the same or similar function. In the lighting device 20 illustrated in FIG. 8, each of the light-emitting elements 10a-10f comprises a substrate 19 and a light-emitting module 1 arranged on the substrate 19. The size of the substrate 19 relatively to the size of the light-emitting module 1 is not necessarily to scale. The substrate 19 and the light-emitting module 1 are indicated by reference numerals only for some of the light-emitting elements. For each of the light-emitting elements 10a-10f, its substrate 19 and the light-emitting module are arranged such that the first outer end surface 11 is located on the substrate 19 and the second outer end surface 12 is located on the light-emitting module 1. Any one or each of the substrate(s) 19 may for example be made at least in part of sapphire. Any one or each of the light-emitting elements 10a-10f may for example comprise at least one CSP LED, wherein the respective light-emitting module 1 may be in the form of a LED die, which may be directly attached to the substrate 19. Any one or each of the light-emitting modules 1 may hence for example comprise or be constituted by at least one CSP LED, and/or another type of LED. It is to be understood that according to one or more other embodiments of the present invention, not all of the light-emitting elements of the lighting device 20 comprises a substrate 19 and a light-emitting module 1 arranged on the substrate 19, and that one or more light-emitting elements of the lighting device 20 may comprise a substrate 19 and a light-emitting module 1 arranged on the substrate 19.

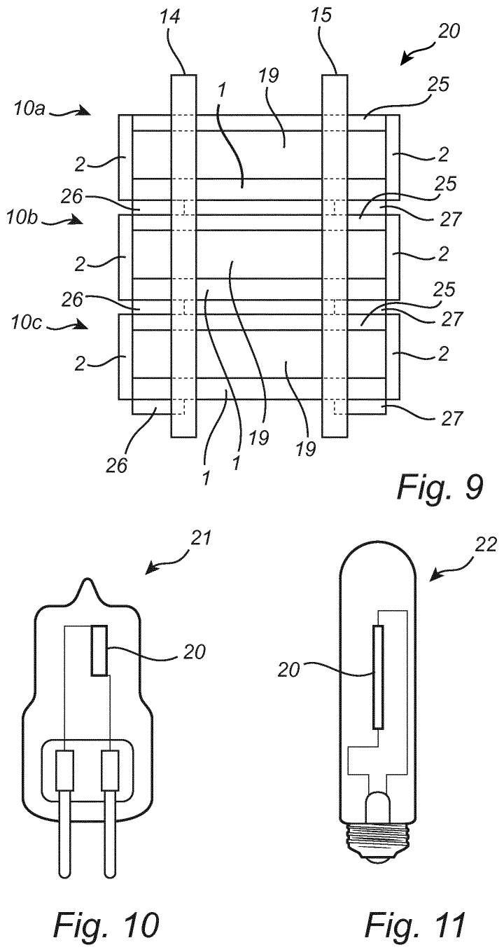

FIG. 9 is a very schematic side view of a lighting device 20 according to an embodiment of the present invention. The lighting device 20 illustrated in FIG. 9 is similar to the lighting device 20 illustrated in FIG. 8, and the same reference numerals in FIGS. 8 and 9 indicate the same or similar components, having the same or similar function. However, in the lighting device 20 illustrated in FIG. 9, the lighting device 20 comprises three light-emitting elements 10a-10c (but the lighting device 20 could comprise less or more than three light-emitting elements), and the connecting structures 14, 15 are connected to a same side of each of the light-emitting elements 10a-10c.

In the lighting device 20 illustrated in FIG. 9, each of the light-emitting elements 10a-10c comprises a substrate 19 and a light-emitting module 1 arranged on a first side of the substrate 19, and a reflector 25 arranged on a second side of the substrate 19. As illustrated in FIG. 9, the first side and the second side of the substrate 19 are opposite sides of the substrate 19. As illustrated in FIG. 9, the first outer end surface 11 of the respective light-emitting elements 10a-10c is located on the reflector 25, and the second outer end surface 12 is located on the light-emitting module 1. The first outer end surface 11 and the second outer end surface 12 of the respective light-emitting elements 10a-10c are not indicated by reference numerals in FIG. 9; see, e.g., FIG. 8.

As illustrated in FIG. 9, each of the light-emitting elements 10a-10c may be provided with an anode 26 and a cathode 27.

In the lighting device 20 illustrated in FIG. 9, each of the light-emitting elements 10a-10c is provided with a wavelength-converting element 2 arranged on a portion of the circumferential surface 13 (not indicated by reference numeral in FIG. 9; see, e.g., FIG. 8) of the respective light-emitting element 10a-10c. The wavelength-converting element 2 of the respective ones of the light-emitting elements 10a-10c is configured so as to receive at least a portion of the light emitted by the light-emitting module 1 and convert the received light into a selected wavelength range. The wavelength-converting element 2 of the respective ones of the light-emitting elements 10a-10c may for example comprise a layer or coating of wavelength-converting material, for example including one or more phosphors.

FIGS. 10 and 11 are schematic views of lamps 21, 22 according to embodiments of the present invention. The lamp 21 is a filament lamp, such as a halogen, or incandescent replacement lamp, and the lamp 22 is an arc lamp, such as a high pressure sodium replacement lamp. Each of the lamps 21 and 22 comprises a lighting device 20 according to an embodiment of the present invention.

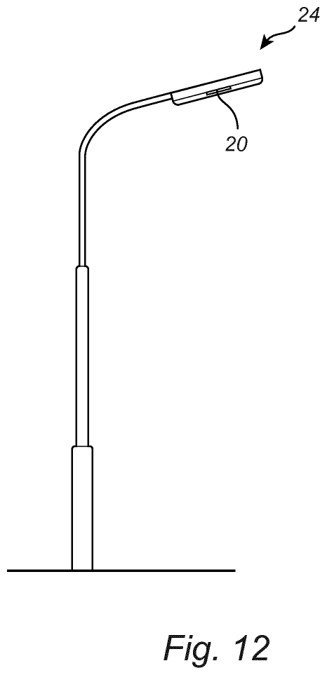

FIG. 12 is a schematic view of a luminaire 24 according to an embodiment of the present invention. The luminaire 24 comprises a lighting device 20 according to an embodiment of the present invention. The luminaire 24 is a street luminaire, or street light, but other types of luminaires are possible.

With reference to any one of the embodiments of the present invention described herein, such as with reference to any one of the FIGS. 2 to 12, the connecting structure(s) of the lighting device may be arranged so as to be reflective, arranged so as to exhibit a heat spreading capacity or capability and/or be configured to provide electrical connection to the light-emitting elements, for example so as to electrically connect the light-emitting elements to a power supply for powering the light-emitting elements.

In conclusion, a lighting device is disclosed, comprising a plurality of light-emitting elements arranged in a succession, for example in a stacked arrangement. The lighting device comprises at least one connecting structure arranged to interconnect at least some of the light-emitting elements, the at least one connecting structure being connected to the at least some of the light-emitting elements at respective outer circumferential surfaces thereof. The lighting device may form a linear light source which may be capable of emitting radially along and around the linear light source.

While the present invention has been illustrated in the appended drawings and the foregoing description, such illustration is to be considered illustrative or exemplifying and not restrictive; the present invention is not limited to the disclosed embodiments. Other variations to the disclosed embodiments can be understood and effected by those skilled in the art in practicing the claimed invention, from a study of the drawings, the disclosure, and the appended claims. In the appended claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A lighting device comprising:
a plurality of light-emitting elements, each light-emitting element comprising a first outer end surface at one end of the light-emitting element, a second outer end surface at another end of the light-emitting element, and an outer circumferential surface extending between the first outer end surface and the second outer end surface, wherein each light-emitting element is configured to emit light at least via at least a portion of the outer circumferential surface of the light-emitting element, wherein the light-emitting elements are arranged in a succession such that at least one of the first outer end surface and the second outer end surface of each light-emitting element is facing in a direction towards a first outer end surface or a second outer end surface of a successive one of the light-emitting elements; and
at least one connecting structure arranged to interconnect at least some of the light-emitting elements, the at least one connecting structure being connected to the at least some of the light-emitting elements at their respective outer circumferential surfaces
wherein each of the light-emitting elements comprises a substrate and a light-emitting module arranged on a first side of the substrate and a reflector arranged on a second side of the substrate, wherein the substrate, the light-emitting module and the reflector are arranged such that the first outer end surface is located on the reflector and the second outer end surface is located on the light-emitting module,
wherein the lighting device having a shape similar to a filament.

2. A lighting device according to claim 1, wherein at least some of the light-emitting elements are arranged in a stacked arrangement such that at least one of the first outer end surface and the second outer end surface of each of the at least some of the light-emitting element is coupled to a first outer end surface or a second outer end surface of a successive one of the at least some of the light-emitting elements, wherein the at least one connecting structure is arranged to fixate the at least some of the light-emitting elements in the stacked arrangement.

3. A lighting device according to claim 1, comprising a plurality of connecting structures arranged to interconnect at least some of the light-emitting elements at their respective outer circumferential surfaces, wherein the connecting structures are connected to each of the at least some of the light-emitting elements at different locations on their respective outer circumferential surfaces.

4. A lighting device according to claim 1, comprising a plurality of connecting structures arranged to interconnect at least some of the light-emitting elements at their respective outer circumferential surfaces, wherein at least one first connecting structure of the connecting structures is arranged to interconnect at least a first plurality of the light-emitting elements at their respective outer circumferential surfaces, and at least one second connecting structure of the connecting structures is arranged to interconnect at least a second plurality of the light-emitting elements at their respective outer circumferential surfaces.

5. (canceled)

6. A lighting device according to claim 1, wherein at least one connecting structure is configured to provide electrical connection to at least one of the light-emitting elements.

7. A lighting device according to claim 1, wherein at least one connecting structure is reflective.

8. A lighting device according to claim 1, wherein at least one of the light-emitting elements comprises a light-emitting module, wherein the lighting device further comprises at least one wavelength-converting element arranged so as to receive at least a portion of the light emitted by the light-emitting module and convert the received light into a selected wavelength range.

9. A lighting device according to claim 1, wherein at least one connecting structure of the at least one connecting structure is arranged so as to exhibit a heat spreading capacity or capability.

10. A lighting device according to claim 1, wherein the light-emitting elements are arranged in a succession in a direction along a central axis of the lighting device, wherein, for at least one of the light-emitting elements, the circumferential width of the light-emitting element in a direction parallel to the central axis differs between different portions of the outer circumferential surface of the light-emitting element.

11. A lighting device according to claim 1, wherein at least a portion of the outer circumferential surface of at least one of the light-emitting elements is non-flat.

12. A lighting device according to claim 1, wherein the light-emitting elements are arranged in a succession in a direction along a central axis of the lighting device, and wherein at least two light-emitting elements are arranged so as to be offset from one another in a direction perpendicular to the direction along the central axis of the lighting device in which the light-emitting elements are arranged.

13. A lighting device according to claim 1, wherein the light-emitting elements are arranged in a succession in a direction along a central axis of the lighting device, and wherein at least two light-emitting elements are arranged so as to be rotated with respect to each other about the central axis or about an axis parallel to the central axis.

14. A lamp or a luminaire comprising at least one lighting device according to claim 1.
